(19) United States
(12) Patent Application Publication
(10) Pub. No.: US 2025/0389752 A1
(43) Pub. Date: Dec. 25, 2025

(54) PROBE PIN AND SOCKET

(71) Applicant: OMRON Corporation, Kyoto-shi (JP)

(72) Inventors: Taichi ONOYAMA, Kyoto-shi (JP); Naoya SASANO, Kyoto-shi (JP); Takahiro SAKAI, Kyoto-shi (JP); Minori YAHAGI, Kyoto-shi (JP); Riku YOSHIMOTO, Kyoto-shi (JP)

(21) Appl. No.: 19/229,342

(22) Filed: Jun. 5, 2025

(30) Foreign Application Priority Data
Jun. 24, 2024 (JP) 2024-101446

(51) Int. Cl. G01R 1/067

(52) U.S. Cl. CPC G01R 1/06716

(57) ABSTRACT

A probe pin includes: a first contact point; a second contact point; a support portion; and an elastic portion connected to the first contact point and the support portion. The elastic portion includes: a plurality of first curved portions; and at least one second curved portion positioned on an opposite side of the plurality of first curved portions with respect to a center line and that protrudes in a direction opposite to the plurality of first curved portions in a second direction. The plurality of first curved portions and the at least one second curved portion are alternately positioned in a first direction. A first imaginary straight line is inclined with respect to the center line, the first imaginary straight line being an imaginary straight line that connects points farthest from the center line in the second direction of two first curved portions adjacent in the first direction.

### CROSS REFERENCE TO RELATED APPLICATIONS

The present invention claims priority under 35 U.S.C. § 119 to Japanese Application No. 2024-101446, filed on Jun. 24, 2024, the entire contents of which being incorporated herein by reference.

### TECHNICAL FIELD

The present disclosure relates to a probe pin and a socket. This application claims priority to Japanese Patent Application No. 2024-101446, entitled “Probe Pin and Socket,” filed Jun. 24, 2024, which is hereby incorporated by reference in its entirety for all purposes.

### BACKGROUND ART

Patent Document 1 discloses a probe pin. The probe pin of Patent Document 1 includes a plate-shaped first contact portion and a plate-shaped second contact portion, an intermediate portion placed between the first contact portion and the second contact portion, a first elastic portion connected to the first contact portion and the intermediate portion, and a second elastic portion connected to the intermediate portion and the second contact portion.

### DESCRIPTION OF THE RELATED ART

Patent Document 1: JPWO 2019-138507 A1

### SUMMARY

The probe pin of Patent Document 1 has room for improvement in terms of improving durability.

An object of the present disclosure is to provide a probe pin and a socket capable of improving durability.

A probe pin according to an aspect of the present disclosure includes:
a first contact point and a second contact point that are spaced apart from each other in a first direction;
a support portion that is positioned between the first contact point and the second contact point in the first direction and that extends in a second direction intersecting the first direction; and
an elastic portion that is connected to the first contact point and the support portion and that is configured to expand and contract in the first direction, wherein
the elastic portion includes:
   a plurality of first curved portions that is positioned on one side with respect to a center line passing through a center of the support portion in the second direction and extending in the first direction, the plurality of first curved portions each protruding in a direction away from the center line in the second direction; and
   at least one second curved portion that is positioned on an opposite side of the plurality of first curved portions with respect to the center line and that protrudes in a direction opposite to the plurality of first curved portions in the second direction,
the plurality of first curved portions and the at least one second curved portion are alternately positioned in the first direction, and
a first imaginary straight line is inclined with respect to the center line, the first imaginary straight line being an imaginary straight line that connects points of two first curved portions adjacent in the first direction among the plurality of first curved portions, the points being farthest from the center line in the second direction.

A socket according to an aspect of the present disclosure includes:
the probe pin according to the aspect; and
a housing that houses the probe pin, wherein
a dimension of the elastic portion in the second direction is smaller than a dimension of the support portion in the second direction, and
the support portion is supported by the housing.

According to the present disclosure, it is possible to provide a probe pin and a socket capable of improving durability.

### BRIEF DESCRIPTION OF DRAWINGS

FIG. 1 is a perspective view illustrating a socket including a probe pin according to an embodiment of the present disclosure;

FIG. 2 is a cross-sectional view taken along line II-II of FIG. 1;

FIG. 3 is a plan view illustrating the probe pin of FIG. 1;

FIG. 4 is a plan view illustrating a first modification of the probe pin of FIG. 1; and

FIG. 5 is a plan view illustrating a second modification of the probe pin of FIG. 1.

### DETAILED DESCRIPTION

Hereinafter, an example of the present disclosure is described with reference to the accompanying drawings. The following description is merely exemplary in nature and does not limit the present disclosure, the applications of the present disclosure, and the uses of the present disclosure. The accompanying drawings are schematic drawings, and the illustrated configuration and the product may have different dimensional ratios and the like. In the following description, terms such as “about” or “substantially” mean that the value, shape, or the like following these terms includes a range of acceptable error as determined by those skilled in the art.

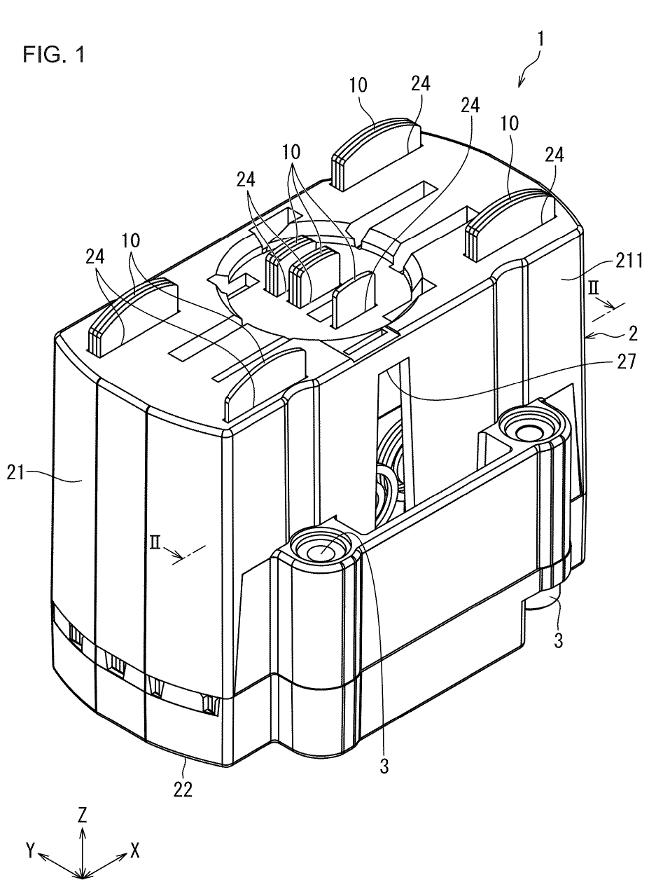

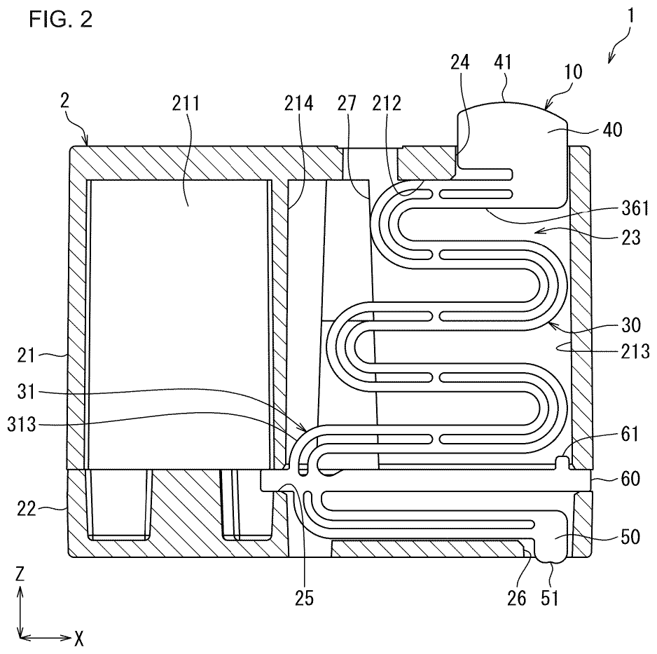

As illustrated in FIG. 1, a probe pin 10 of an embodiment of the present disclosure constitutes a part of a socket 1. As an example, the socket 1 includes a plurality of probe pins 10 and a housing 2 that houses the plurality of probe pins 10 in a mutually electrically independent state. As illustrated in FIG. 2, the probe pins 10 each have, for example, an elongated thin plate shape formed by any processing method including electroforming and pressing using a conductive material and have substantially the same configuration.

As illustrated in FIG. 1, the housing 2 includes, as an example, an insulating housing body 21 and a lid portion 22.

As illustrated in FIG. 2, the housing body 21 includes housing portions 23 that are provided inside the housing body and house the probe pins 10, a first opening portion 24 provided at one end in a first direction Z, and a second opening portion 25 provided at the other end in the first direction Z. As illustrated in FIG. 1, each housing portion 23 is configured to house one probe pin 10 or is configured to house three probe pins 10 arranged in a contact state in a plate thickness direction (for example, in a Y direction). Each housing portion 23 has a substantially rectangular shape when viewed in the plate thickness direction Y. The first opening portion 24 and the second opening portion 25 are connected to the housing portion 23. The first opening portion 24 is configured to house a first contact point 40, which is described below, of the probe pin 10. The second opening portion 25 is configured to house the probe pin 10 from a longitudinal direction (for example, a Z direction (hereinafter, referred to as a first direction Z)) of the housing portion 23.

The housing body 21 includes a through hole 27 provided in a side surface 211 in the plate thickness direction Y of the probe pin 10 housed in the housing portion 23. The through hole 27 penetrates the side surface 211 of the housing body 21 in the plate thickness direction Y of the probe pin 10 housed in the housing portion 23.

The lid portion 22 is attached to an end portion of the housing body 21 on a second opening portion 25 side by, for example, a fastening member 3 (see FIG. 1) to cover the second opening portion 25. The lid portion 22 includes a third opening portion 26 provided in a portion facing the second opening portion 25 in a state in which the lid portion 22 is attached to the housing body 21. The third opening portion 26 is configured to house a second contact point 50, which is described below, of the probe pin 10. In the state in which the lid portion 22 is attached to the housing body 21, the third opening portion 26 is located at a position overlapping the first opening portion 24 as viewed in the first direction Z.

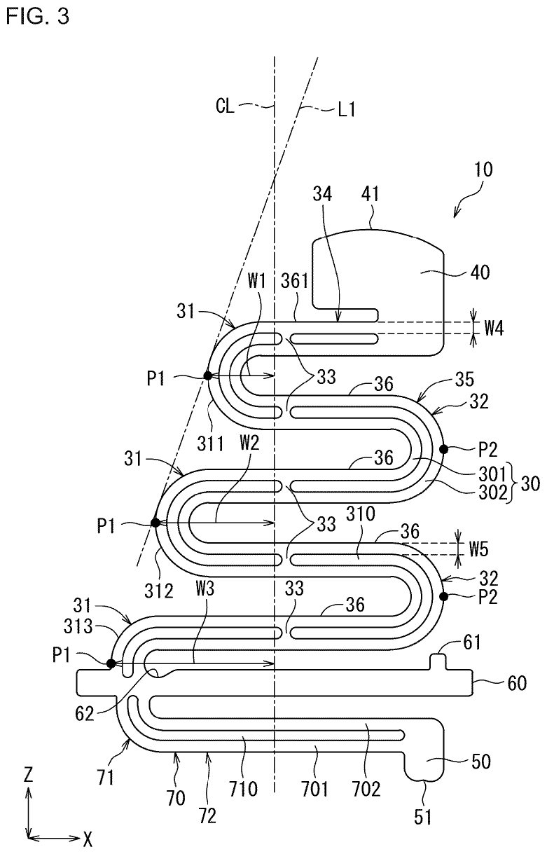

As illustrated in FIG. 3, the probe pin 10 includes an elastic portion 30, the first contact point 40, the second contact point 50, and a support portion 60. The first contact point 40 and the second contact point 50 are spaced apart from each other in the first direction Z. The support portion 60 is positioned between the first contact point 40 and the second contact point 50 in the first direction Z, and extends in a second direction (for example, in an X direction,) intersecting (for example, orthogonal to) the first direction Z. The elastic portion 30 is connected to the first contact point 40 and the support portion 60, and is configured to expand and contract in the first direction Z. As illustrated in FIG. 2, a distal portion 41 of the first contact point 40 in the first direction Z is positioned outside the housing 2, the distal portion 41 being an end portion far from the elastic portion 30 in both end portions of the first contact point 40 in the first direction Z. A distal end portion 51 of the second contact point 50 in the first direction Z is positioned outside the housing 2, the distal end portion 51 being an end portion far from the elastic portion 30 in both end portions of the second contact point 50 in the first direction Z.

As illustrated in FIG. 3, the elastic portion 30 has a shape including a substantially S-shape as viewed in a third direction (for example, the plate thickness direction Y) intersecting (for example, orthogonal to) the first direction Z and the second direction X. The elastic portion 30 includes a plurality of first curved portions 31 and at least one second curved portion 32. In this aspect, the elastic portion 30 includes three first curved portions 31 and two second curved portions 32. The three first curved portions 31 are spaced apart from each other in the first direction Z. Each second curved portion 32 is positioned between two first curved portions 31 adjacent in the first direction Z. In other words, the first curved portions 31 and the second curved portions 32 are alternately positioned in the first direction Z.

Each of the first curved portions 31 is positioned on one side with respect to a center line CL passing through the center of the support portion 60 in the second direction X and extending in the first direction Z, and protrudes in a direction away from the center line CL in the second direction X. In this aspect, each first curved portion 31 is positioned on the opposite side of the first contact point 40 and the second contact point 50 with respect to the center line CL. Of the three first curved portions 31, the first curved portion 31 closest to the first contact point 40 in the first direction Z is defined as a curved portion 311, the first curved portion 31 second closest to the first contact point 40 in the first direction Z is defined as a curved portion 312, and the first curved portion 31 closest to the second contact point 50 is defined as a curved portion 313. As viewed in the third direction Y, the curved portions 311 and 312 have a substantially semicircular shape, and the curved portion 313 has a sector shape of a substantially ¼ circle. One end of the curved portion 311 in an extending direction in which the elastic portion 30 extends (in other words, a direction along the shape of the elastic portion 30) is connected to the support portion 60. The other end of the curved portion 311 in the extending direction of the elastic portion 30 is connected to the second curved portion 32 positioned near the second contact point 50 in the first direction Z.

A point farthest from the center line CL in the second direction X of each first curved portion 31 is defined as “P1”. A first distance between the center line CL and the point P1 in the second direction X increases as a distance from the first contact point 40 increases in the first direction Z. When the first distance of the curved portion 311 is defined as “W1”, the first distance of the curved portion 312 is defined as “W2”, and the first distance of the curved portion 313 is defined as “W3”, the first distances W1, W2, W3 have a relationship of “W1<W2<W3”. When an imaginary straight line that connects points P1 of curved portions (for example, the curved portions 311, 312) adjacent in the first direction Z among the three first curved portions 31 is defined as a first imaginary straight line L1, the first imaginary straight line L1 is inclined with respect to the center line CL.

Each of the second curved portions 32 is positioned on the opposite side of the first curved portion 31 with respect to the center line CL, and protrudes in a direction opposite to the first curved portion 31 in the second direction X. A point farthest from the center line CL in the second direction X of each second curved portion 32 is defined as “P2”. In this aspect, a second distance between the center line CL and the points P2 in the second direction X is substantially the same in all the second curved portions 32.

In this aspect, the elastic portion 30 includes a plurality of elastic pieces (in this aspect, two elastic pieces 301, 302) and at least one connecting portion 33 (in this aspect, five connecting portions 33). The two elastic pieces 301, 302 are spaced apart from each other with a gap 310 in a width direction intersecting (for example, orthogonal to) the extending direction of the elastic portion 30. Both ends in the width direction of each connecting portion 33 are connected to two elastic pieces (in this aspect, the elastic pieces 301, 302) adjacent in the width direction among the plurality of elastic pieces. Each connecting portion 33 is positioned between the first curved portion 31 and the second curved portion 32 in the second direction X. In this aspect, each connecting portion 33 is adjacent to the center line CL and extends substantially parallel to the center line CL. The five connecting portions 33 are positioned at substantially the same distance from the center line CL in the second direction X.

In this aspect, the elastic portion 30 includes a first portion 34 that is a portion between the first contact point 40 and the connecting portion 33 closest to the first contact point 40, and a second portion 35 that is a portion other than the first portion 34. The elastic portion 30 is configured such that a dimension in the width direction of the first portion 34 (for example, a dimension W4 of the elastic piece 301 in the width direction of the first portion 34) is larger than a dimension in the width direction of the second portion 35 (for example, a dimension W5 of the elastic piece 301 in the width direction of the second portion 35).

As illustrated in FIG. 3, the elastic portion 30 includes a plurality of non-curved portions 36 (in this aspect, five non-curved portions 36) extending linearly along the second direction X. In the non-curved portion 36 positioned closest to the first contact point 40 in the first direction Z, one end in the second direction X is connected to the curved portion 311, and the other end in the second direction X is connected to the first contact point 40. As illustrated in FIG. 2, in a state in which the probe pin 10 is housed in the housing portion 23, the non-curved portion 36 positioned closest to the first contact point 40 in the first direction Z (for example, the non-curved portion 361) is in contact with an inner surface 212 of the housing body 21 constituting the housing portion 23. The non-curved portion 36 except the non-curved portion 361 includes one end in the second direction X connected to the first curved portion 31 and the other end in the second direction X connected to the second curved portion 32.

As illustrated in FIG. 3, the first contact point 40 and the second contact point 50 are positioned on the same side in the second direction X as the second curved portion 32 with respect to the center line CL. The first contact point 40 and the second contact point 50 have, for example, shapes and sizes corresponding to a terminal of an inspection device or an inspection object.

As illustrated in FIG. 3, as an example, the support portion 60 has a substantially rectangular shape, and is configured such that a dimension of the support portion 60 in the second direction X is larger than a dimension of the elastic portion 30 in the second direction X. In other words, in this aspect, the dimension of the elastic portion 30 in the second direction X is smaller than the dimension of the support portion 60 in the second direction X. In this aspect, as illustrated in FIG. 2, both ends of the support portion 60 in the second direction X are held between the housing body 21 and the lid portion 22. This causes the support portion 60 to be supported by the housing 2, and restricts a movement of the probe pin 10 in the first direction Z.

As illustrated in FIG. 3, the support portion 60 includes a projection 61. The projection 61 is positioned on the opposite side of the first curved portion 31 with respect to the center line CL, and extends from the support portion 60 toward the first contact point 40 in the first direction Z. As illustrated in FIG. 2, the projection 61 is configured to face an inner surface 213 of the housing body 21 constituting the housing portion 23 in the second direction X. The inner surface 213 extends in the first direction Z and intersects with the inner surface 212.

In this aspect, of the first curved portions 31 and the second curved portions 32, the first curved portion 31 is positioned closest to the support portion 60 in the first direction Z. As illustrated in FIG. 2, the first curved portion 31 closest to the support portion 60 in the first direction Z (that is, the curved portion 313) faces an inner surface 214 of the housing body 21 constituting the housing portion 23 in the second direction X. The inner surface 214 extends in the first direction Z, intersects with the inner surface 212, and faces the inner surface 213 in the second direction X. The projection 61 and the first curved portion 31 (that is, the curved portion 313) restrict a movement of the probe pin 10 in the second direction X.

The support portion 60 includes a portion that faces the elastic portion 30 and is provided with a recessed portion 62 recessed from the first contact point 40 toward the second contact point 50 in the first direction Z. The recessed portion 62 is adjacent to the curved portion 313 in the second direction X and is positioned closer to the center line CL than the curved portion 313.

In this aspect, the probe pin 10 includes an elastic portion 70 that connects the second contact point 50 and the support portion 60. As an example, the elastic portion 70 includes a curved portion 71 positioned on a first curved portion 31 side with respect to the center line CL and a non-curved portion 72 extending in the second direction X. The curved portion 71 has a sector shape of substantially ¼ circle, and is located at a position overlapping the curved portion 313 as viewed in the first direction Z. The elastic portion 70 includes two elastic pieces 701, 702 spaced apart from each other with a gap 710. One end of the curved portion 71 in an extending direction in which the curved portion 71 extends (in other words, a direction along the shape of the elastic portion 70) is connected to the support portion 60, and the other end of the curved portion 71 in the extending direction of the curved portion 71 is connected to the non-curved portion 72. One end of the non-curved portion 72 in the second direction X is connected to the curved portion 71, and the other end of the non-curved portion 72 in the second direction X is connected to the second contact point 50.

The probe pin 10 can exhibit the following advantageous effects.

The probe pin 10 includes the first contact point 40 and the second contact point 50 spaced apart from each other in the first direction Z, the support portion 60, and the elastic portion 30. The support portion 60 is positioned between the first contact point 40 and the second contact point 50 in the first direction Z and extends in the second direction X. The elastic portion 30 is connected to the first contact point 40 and the support portion 60, and is configured to expand and contract in the first direction Z. The elastic portion 30 includes the plurality of first curved portions 31 and the at least one second curved portion 32. The plurality of first curved portions 31 are positioned on one side with respect to the center line CL that passes through the center of the support portion 60 in the second direction X and extends in the first direction Z. Each first curved portion 31 protrudes in the direction away from the center line CL in the second direction X. At least one second curved portion 32 is positioned on the opposite side of the first curved portion 31 with respect to the center line CL, and protrudes in the direction opposite to the first curved portion 31 in the second direction X. The first curved portions 31 and the second curved portions 32 are alternately positioned in the first direction Z. The first imaginary straight line L1 is inclined with respect to the center line CL, the first imaginary straight line L1 being an imaginary straight line that connects the points P1 of two first curved portions 31 adjacent in the first direction Z among the plurality of first curved portions 31, the points P1 being farthest from the center line CL in the second direction X. Such a configuration makes it possible to adjust a balance of stress applied to the elastic portion 30, providing the probe pin 10 capable of improving durability.

The elastic portion 30 includes the plurality of elastic pieces and the at least one connecting portion 33. The plurality of elastic pieces is spaced apart from each other with the gap 310 in the width direction. The connecting portion 33 includes two ends in the width direction that are respectively connected to two adjacent elastic pieces 301, 302 among the plurality of elastic pieces. The connecting portion 33 is positioned between the first curved portion 31 and the second curved portion 32 in the second direction X. Such a configuration makes it possible to adjust the balance of the stress applied to the elastic portion 30 more reliably.

The elastic portion 30 includes the first portion 34 and the second portion 35. The first portions 34 is a portion between the first contact point 40 and the connecting portion 33 closest to the first contact point 40. The second portion 35 is a portion other than the first portion 34. The dimension of the first portion 34 in the width direction is larger than the dimension of the second portion 35 in the width direction. Such a configuration makes it possible to adjust the balance of the stress applied to the elastic portion 30 more reliably.

The socket 1 can exhibit the following advantageous effects.

The socket 1 includes the probe pins 10 and the housing 2 that houses the probe pins 10. The dimension of each elastic portion 30 in the second direction X is smaller than the dimension of the support portion 60 in the second direction X, and the support portion 60 is supported by the housing 2. Such a configuration makes it possible to provide the socket 1 capable of improving durability.

Of the first curved portions 31 and the second curved portions 32, the first curved portion 31 is positioned closest to the support portion 60 in the first direction Z. The support portion 60 includes the projection 61 positioned on the opposite side of the first curved portion 31 with respect to the center line CL. The projection 61 extends from the support portion 60 toward the first contact point 40 in the first direction Z. The projection 61 and the first curved portion 31 are configured to contact the housing 2 in the second direction X to restrict a movement of the probe pin 10 in the second direction X. Such a configuration makes it possible to provide the socket 1 capable of improving durability more reliably.

The probe pin 10 may be configured as follows.

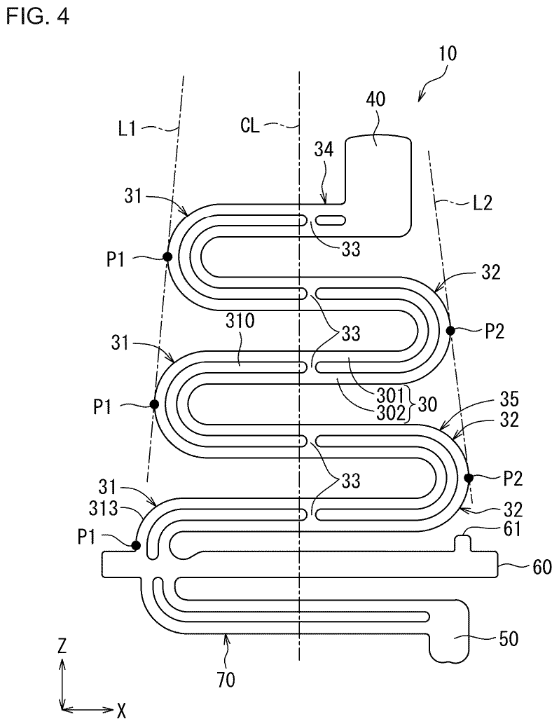

As illustrated in FIG. 4, the elastic portion 30 may be configured such that the elastic portion 30 includes a plurality of the second curved portions 32 each including the point P2 and such that a second imaginary straight line L2 is inclined with respect to the center line CL, the second imaginary straight line L2 being an imaginary straight line that connects the points P2 of each of the plurality of second curved portions. Such a configuration makes it possible to adjust the balance of the stress applied to the elastic portion 30 more reliably.

In the probe pin 10 illustrated in FIG. 4, the size of the first contact point 40 and the length of the first portion 34 in the second direction X as viewed in the third direction Y are smaller than those of the probe pin 10 illustrated in FIG. 3. The inclination angle with respect to the center line CL of the first imaginary straight line L1 is smaller than that of probe pin 10 illustrated in FIG. 3.

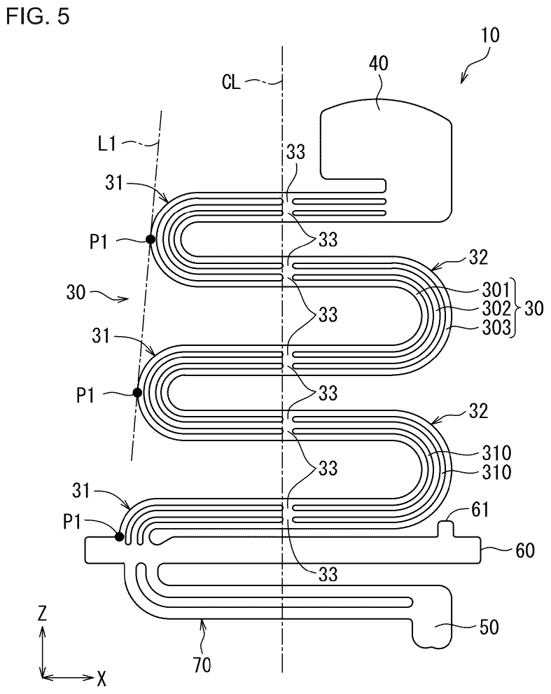

The elastic portion 30 may include just one elastic piece or may include three or more elastic pieces. FIG. 5 illustrates an example of the probe pin 10 including the elastic portion 30 including three elastic pieces 301, 302, 303. Two elastic pieces adjacent in the width direction are provided with the gap 310. The connecting portion 33 may be placed at any position between the first curved portion 31 and the second curved portion 32 in the second direction X. For example, in the probe pin 10 illustrated in FIG. 5, the elastic portion 30 includes ten connecting portions 33. The ten connecting portions 33 are positioned closer to the center line CL than the connecting portion 33 of the probe pin 10 illustrated in FIG. 3.

In the probe pin 10 illustrated in FIGS. 3 to 5, the first contact point 40 and the second contact point 50 are positioned on the same side as the second curved portions 32 with respect to the center line CL in the second direction X, but the present invention is not limited thereto. For example, the first contact point 40 and the second contact point 50 may be configured that in the second direction X, the first contact point 40 and the second contact point 50 is positioned on the same side as the first curved portions 31 with respect to the center line CL, or the first contact point 40 is positioned on the same side as the first curved portions 31 with respect to the center line CL and the second contact point 50 is positioned on the same side as the second curved portions 32 with respect to the center line CL.

The elastic pieces 301, 302 and the gap 310 may or may not have a constant dimension in the width direction. In other words, the elastic portion 30 may or may not include the first portion 34 and the second portion 35.

As described above, the configuration of each portion (for example, the elastic portion 30, the first contact point 40, and the second contact point 50) of the probe pin 10 may be changed according to design or the like of the probe pin 10.

Various aspects of the present disclosure are described below with reference numerals.

A probe pin 10 according to a first aspect of the present disclosure includes:
a first contact point 40 and a second contact point 50 that are spaced apart from each other in a first direction;
a support portion 60 that is positioned between the first contact point 40 and the second contact point 50 in the first direction and that extends in a second direction intersecting the first direction; and
an elastic portion 30 that is connected to the first contact point 40 and the support portion 60 and that is configured to expand and contract in the first direction, wherein
the elastic portion 30 includes:
   a plurality of first curved portions 31 that is positioned on one side with respect to a center line CL passing through a center of the support portion 60 in the second direction and extending in the first direction, the plurality of first curved portions 31 each protruding in a direction away from the center line CL in the second direction; and
   at least one second curved portion 32 that is positioned on an opposite side of the plurality of first curved portions 31 with respect to the center line CL and that protrudes in a direction opposite to the plurality of first curved portions 31 in the second direction,
the plurality of first curved portions 31 and the at least one second curved portion 32 are alternately positioned in the first direction, and
a first imaginary straight line L1 is inclined with respect to the center line CL, the first imaginary straight line L1 being an imaginary straight line that connects points P1 of two first curved portions 31 adjacent in the first direction among the plurality of first curved portions 31, the points being farthest from the center line CL1 in the second direction.

A probe pin 10 according to a second aspect of the present disclosure is the probe pin 10 according to the first aspect, wherein
the elastic portion 30 includes:
   a plurality of elastic pieces that is spaced apart from each other with a gap in a width direction intersecting an extending direction in which the elastic portion 30 extends; and
   at least one connecting portion 33 including both ends in the width direction, the both ends being respectively connected to two adjacent elastic pieces among the plurality of elastic pieces, and
the at least one connecting portion 33 is positioned between a first curved portion among the plurality of first curved portions 31 and the at least one second curved portion 32 in the second direction.

A probe pin 10 according to a third aspect of the present disclosure is the probe pin 10 according to the second aspect, wherein
the elastic portion 30 includes a first portion 34 that is a portion between the first contact point 40 and the connecting portion 33 closest to the first contact point 40, and a second portion 35 that is a portion other than the first portion 34, and
a dimension of the first portion 34 in the width direction is larger than a dimension of the second portion 35 in the width direction.

A probe pin 10 according to a fourth aspect of the present disclosure is the probe pin 10 according to any of the first to third aspects, wherein
the at least one connecting portion 33 includes a plurality of second curved portions 32, and
a second imaginary straight line L2 is inclined with respect to the center line CL, the second imaginary straight line L2 being an imaginary straight line that connects points P2 farthest from the center line CL in the second direction of each of the plurality of second curved portions 32.

A socket 1 according to a fifth aspect of the present disclosure includes:
the probe pin 10 according to any of the first to third aspects; and
a housing 2 that houses the probe pin 10, wherein
a dimension of the elastic portion 30 in the second direction is smaller than a dimension of the support portion 60 in the second direction, and
the support portion 60 is supported by the housing 2.

A socket 1 according to a sixth aspect of the present disclosure is the socket 1 according to the fifth aspect, wherein
of the plurality of first curved portions 31 and the at least one second curved portion 32, a first curved portions 31 is positioned closest to the support portion 60 in the first direction,
the support portion 60 includes a projection 61 that is positioned on an opposite side of the first curved portion 31 with respect to the center line CL and that extends from the support portion 60 toward the first contact point 40 in the first direction, and
the projection 61 and the first curved portion 31 are configured to contact the housing 2 in the second direction to restrict a movement of the probe pin 10 in the second direction.

The embodiments and modifications of the present disclosure can be a combination of the embodiments, a combination of the modifications, or a combination of the embodiments and the modifications. It is also possible to combine features included in the embodiments and modifications of the present disclosure.

The contents of the present disclosure are appropriate to change in details of the configuration, and changes in combination and order of elements in each embodiment can be realized without departing from the scope and spirit of the claimed present disclosure.

The probe pin and the socket of the present disclosure can be used, for example, for inspection of batteries.

1. A probe pin, comprising:
a first contact point and a second contact point that are spaced apart from each other in a first direction;
a support portion that is positioned between the first contact point and the second contact point in the first direction and that extends in a second direction intersecting the first direction; and
an elastic portion that is connected to the first contact point and the support portion and that is configured to expand and contract in the first direction, wherein
the elastic portion includes:
a plurality of first curved portions that is positioned on one side with respect to a center line passing through a center of the support portion in the second direction and extending in the first direction, the plurality of first curved portions each protruding in a direction away from the center line in the second direction; and
at least one second curved portion that is positioned on an opposite side of the plurality of first curved portions with respect to the center line and that protrudes in a direction opposite to the plurality of first curved portions in the second direction,
the plurality of first curved portions and the at least one second curved portion are alternately positioned in the first direction, and
a first imaginary straight line is inclined with respect to the center line, the first imaginary straight line being an imaginary straight line that connects points of two first curved portions adjacent in the first direction among the plurality of first curved portions, the points being farthest from the center line in the second direction.

2. A probe pin according to claim 1, wherein
the elastic portion includes:
a plurality of elastic pieces that is spaced apart from each other with a gap in a width direction intersecting an extending direction in which the elastic portion extends; and
at least one connecting portion including both ends in the width direction, the ends being respectively connected to two adjacent elastic pieces among the plurality of elastic pieces, and
the at least one connecting portion is positioned between a first curved portion among the plurality of first curved portions and the at least one second curved portion in the second direction.

3. A probe pin according to claim 2, wherein
the elastic portion includes a first portion that is a portion between the first contact point and the connecting portion closest to the first contact point, and a second portion that is a portion other than the first portion, and
a dimension of the first portion in the width direction is larger than a dimension of the second portion in the width direction.

4. A probe pin according to claim 1, wherein
the at least one second curved portion includes a plurality of second curved portions, and
a second imaginary straight line is inclined with respect to the center line, the second imaginary straight line being an imaginary straight line that connects points farthest from the center line in the second direction of each of the plurality of second curved portions.

5. A probe pin according to claim 2, wherein
the at least one second curved portion includes a plurality of second curved portions, and
a second imaginary straight line is inclined with respect to the center line, the second imaginary straight line being an imaginary straight line that connects points farthest from the center line in the second direction of each of the plurality of second curved portions.

6. A probe pin according to claim 3, wherein
the at least one second curved portion includes a plurality of second curved portions, and
a second imaginary straight line is inclined with respect to the center line, the second imaginary straight line being an imaginary straight line that connects points farthest from the center line in the second direction of each of the plurality of second curved portions.

7. A socket, comprising:
the probe pin according to claim 1; and
a housing that houses the probe pin, wherein
a dimension of the elastic portion in the second direction is smaller than a dimension of the support portion in the second direction, and
the support portion is supported by the housing.

8. A socket according to claim 7, wherein
of the plurality of first curved portions and the at least one second curved portion, a first curved portion is positioned closest to the support portion in the first direction,
the support portion includes a projection that is positioned on an opposite side of the first curved portion with respect to the center line and that extends from the support portion toward the first contact point in the first direction, and
the projection and the first curved portion are configured to contact the housing in the second direction to restrict a movement of the probe pin in the second direction.

9. A socket, comprising:
the probe pin according to claim 2; and
a housing that houses the probe pin, wherein
a dimension of the elastic portion in the second direction is smaller than a dimension of the support portion in the second direction, and
the support portion is supported by the housing.

10. A socket according to claim 9, wherein
of the plurality of first curved portions and the at least one second curved portion, a first curved portion is positioned closest to the support portion in the first direction,
the support portion includes a projection that is positioned on an opposite side of the first curved portion with respect to the center line and that extends from the support portion toward the first contact point in the first direction, and
the projection and the first curved portion are configured to contact the housing in the

11. A socket, comprising:
the probe pin according to claim 3; and
a housing that houses the probe pin, wherein
a dimension of the elastic portion in the second direction is smaller than a dimension of the support portion in the second direction, and
the support portion is supported by the housing.

12. A socket according to claim 11, wherein
of the plurality of first curved portions and the at least one second curved portion, a first curved portion is positioned closest to the support portion in the first direction,
the support portion includes a projection that is positioned on an opposite side of the first curved portion with respect to the center line and that extends from the support portion toward the first contact point in the first direction, and
the projection and the first curved portion are configured to contact the housing in the second direction to restrict a movement of the probe pin in the second direction.

13. A socket, comprising:
the probe pin according to claim 4; and
a housing that houses the probe pin, wherein
a dimension of the elastic portion in the second direction is smaller than a dimension of the support portion in the second direction, and
the support portion is supported by the housing.

14. A socket according to claim 13, wherein
of the plurality of first curved portions and the at least one second curved portion, a first curved portion is positioned closest to the support portion in the first direction,
the support portion includes a projection that is positioned on an opposite side of the first curved portion with respect to the center line and that extends from the support portion toward the first contact point in the first direction, and
the projection and the first curved portion are configured to contact the housing in the second direction to restrict a movement of the probe pin in the second direction.

15. A socket, comprising:
the probe pin according to claim 5; and
a housing that houses the probe pin, wherein
a dimension of the elastic portion in the second direction is smaller than a dimension of the support portion in the second direction, and
the support portion is supported by the housing.

16. A socket according to claim 15, wherein
of the plurality of first curved portions and the at least one second curved portion, a first curved portion is positioned closest to the support portion in the first direction,
the support portion includes a projection that is positioned on an opposite side of the first curved portion with respect to the center line and that extends from the support portion toward the first contact point in the first direction, and
the projection and the first curved portion are configured to contact the housing in the second direction to restrict a movement of the probe pin in the second direction.

17. A socket, comprising:
the probe pin according to claim 6; and
a housing that houses the probe pin, wherein
a dimension of the elastic portion in the second direction is smaller than a dimension of the support portion in the second direction, and
the support portion is supported by the housing.

18. A socket according to claim 17, wherein
of the plurality of first curved portions and the at least one second curved portion, a first curved portion is positioned closest to the support portion in the first direction,
the support portion includes a projection that is positioned on an opposite side of the first curved portion with respect to the center line and that extends from the support portion toward the first contact point in the first direction, and
the projection and the first curved portion are configured to contact the housing in the second direction to restrict a movement of the probe pin in the second direction.
